(19) United States
(12) Patent Application Publication
(10) Pub. No.: US 2017/0148750 A1
(43) Pub. Date: May 25, 2017

(54) ON-DIE INDUCTOR WITH IMPROVED Q-FACTOR

(71) Applicant: INTEL CORPORATION, Santa Clara, CA (US)

(72) Inventors: Ruchir SARASWAT, Wiltshire (GB); Uwe ZILLMANN, Braunschweig (DE); Nicholas P. COWLEY, Wiltshire (GB); Richard J. GOLDMAN, Gloucestershire (GB)

(73) Assignee: Intel Corporation

(21) Appl. No.: 15/323,615

(22) PCT Filed: Aug. 7, 2014
(86) PCT No.: PCT/US2014/050133

§ 371 Date: Jan. 3, 2017

(51) Int. Cl. H01L 23/64; H01F 41/04; H01L 49/02; H01F 27/28

(52) U.S. Cl. CPC H01L 23/645; H01F 27/2804; H01F 41/041; H01L 28/10

(57) ABSTRACT

Described is an apparatus which comprises: a substrate; a plurality of holes formed as vias (e.g., through-silicon-vias (TSVs)) in the substrate; and a metal loop formed in a metal layer positioned above the plurality of holes such that a plane of the metal loop is orthogonal to the plurality of holes.

### BACKGROUND

On die inductors suffer from both Eddy and displacement currents leading to substrate loss. This loss reduces performance of the on die inductors. Here, inductor performance is described with reference to Q-factor. The substrate losses lead to a lower Q-factor which generally means higher losses. Q-factor can be expressed as:

Q-factor=ωL/R.

where, ‘ω’ is the frequency, ‘L’ is the inductance, and ‘R’ is the ESR (i.e., equivalent series resistance) of the inductor coil. As ‘R’ decreases, Q-factor increases. The Q-factor of an inductor is the ratio of its inductive reactance to its resistance at a given frequency, and is a measure of its efficiency. The higher the Q-factor of the inductor, the closer the inductor approaches the behavior of an ideal, lossless, inductor.

One method of reducing Eddy and displacement currents is to use a solid ground shield underneath the inductor coil. FIG. 1A illustrates a top view of die 100 with an inductor 101 formed orthogonal to a layer of solid ground shield 102. A drawback with this approach is that the solid ground shield 102 also disturbs the magnetic field of inductor 101. According to Lenz's Law, image current, also known as loop current, is induced in the solid ground shield 102 by the magnetic field of spiral inductor 101. The image current in solid ground shield 102 flows in a direction opposite to that of the current in the inductor spiral 101. The resulting negative mutual coupling between the current reduces the magnetic field, and thus the overall inductance (i.e., reduces the Q-factor).

An alternative approach to reducing Eddy and displacement currents is to pattern the ground shield. FIG. 1B illustrates a top view of die 120 having an inductor 101 formed orthogonal to a layer of patterned ground shield 122. The purpose of patterned ground shield 122 is to increase the impedance for the Eddy current and hence make the characteristics of inductor 101 less dependent on the type of substrate (here, patterned ground shield 122). However, such a scheme entails using a lower metal layer (e.g., when the inductor is in a higher metal layer in the active region of the die) for patterning which leads to loss of metal layer in the active region (i.e., front part) of die 120.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1A illustrates a top view of a die having an inductor formed orthogonal to a layer of solid ground shield.

FIG. 1B illustrates a top view of a front part of a die having an inductor formed orthogonal to a layer of patterned ground shield.

FIG. 2A illustrates a top view of a die having a device orthogonal to holes of through-silicon-vias (TSVs), according to some embodiments of the disclosure.

FIG. 2B illustrates three dimensional (3D) view of a die having a metal loop orthogonal to holes of TSVs, according to some embodiments of the disclosure.

FIG. 3A illustrates a top view of a die having a layer of uniform pattern of holes of TSVs orthogonal to a metal loop, according to some embodiments of the disclosure.

FIG. 3B illustrates a top view of a die having a layer of sparsely spaced holes of TSVs orthogonal to a metal loop, according to some embodiments of the disclosure.

FIG. 3C illustrates a top view of a die having a layer of uniform pattern of wider holes of TSVs orthogonal to a metal loop, according to some embodiments of the disclosure.

FIGS. 3D-E illustrate top views of dies each having a layer of pattern of holes of TSVs directly orthogonal to a metal loop, according to some embodiments of the disclosure.

FIGS. 4A-B illustrate plots indicating improvement of Q-factor using the embodiments compared to prior art approaches.

FIG. 5 illustrates a method of forming an inductor with an orthogonal layer of TSV holes, according to some embodiments of the disclosure.

FIG. 6 illustrates an LC oscillator using the inductor with an orthogonal layer of TSV holes, according to some embodiments of the disclosure.

FIG. 7 illustrates a top view of a backside of a die having an inductor formed orthogonal to a layer of patterned ground shield, according to some embodiments of the disclosure.

FIG. 8 illustrates a smart device or a computer system or an SoC (System-on-Chip) having a metal loop formed orthogonal to holes of TSVs, according to one embodiment of the disclosure.

### DETAILED DESCRIPTION

Some embodiments describe an apparatus and method to break the loop current path (or Eddy current path) by using a plurality of holes formed from vias (e.g., Through-Silicon-Vias (TSVs)) which are formed orthogonal to a layer of a metal loop formed in a metal layer. In some embodiments, the silicon underneath the metal loop is etched away to break the Eddy current path. In some embodiments, a known TSV process path is used but the TSVs are not filled with metal. For example, holes are dug in a substrate to create TSVs, SiO₂ layer is grown on the side walls, and the step of filling the TSVs with conductive material is skipped. In some embodiments, TSVs are filled with non-conductive material to provide mechanical strength to the die. While the embodiments are described with reference to TSVs, other types of vias formed in the substrate may also be used.

In some embodiments, the TSVs used for providing signals (i.e., to couple to the two terminals of the metal loop) are the TSV holes that are filled with conductive material. In some embodiments, the metal loop can be formed using a thick metal layer on the active side of the die (i.e., front-side of the substrate having active devices) or on the backside of die using a redistribution metal layer (RDL). The inductor formed from some embodiments can be used for any circuit that uses an inductor. For example, the inductor can be used in LC-PLLs (inductor-capacitor based Phase Locked Loop), RF (radio-frequency) circuits, filters, etc.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct electrical connection between the things that are connected, without any intermediary devices. The term “coupled” means either a direct electrical connection between the things that are connected or an indirect connection through one or more passive or active intermediary devices. The term “circuit” means one or more passive and/or active components that are arranged to cooperate with one another to provide a desired function. The term “signal” means at least one current signal, voltage signal or data/clock signal. The meaning of “a,” “an,” and “the” include plural references. The meaning of “in” includes “in” and “on.”

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level. The terms “substantially,” “close,” “approximately,” “near,” and “about,” generally refer to being within +/−20% of a target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For purposes of the embodiments, the transistors are metal oxide semiconductor (MOS) transistors, which include drain, source, gate, and bulk terminals. The transistors also include Tri-Gate and FinFET transistors, Gate All Around Cylindrical Transistors, Tunneling FET (TFET), Square Wire, or Rectangular Ribbon Transistors or other devices implementing transistor functionality like carbon nano tubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, eFET, etc., may be used without departing from the scope of the disclosure. The term “MN” indicates an n-type transistor (e.g., NMOS, NPN BJT, etc.) and the term “MP” indicates a p-type transistor (e.g., PMOS, PNP BJT, etc.).

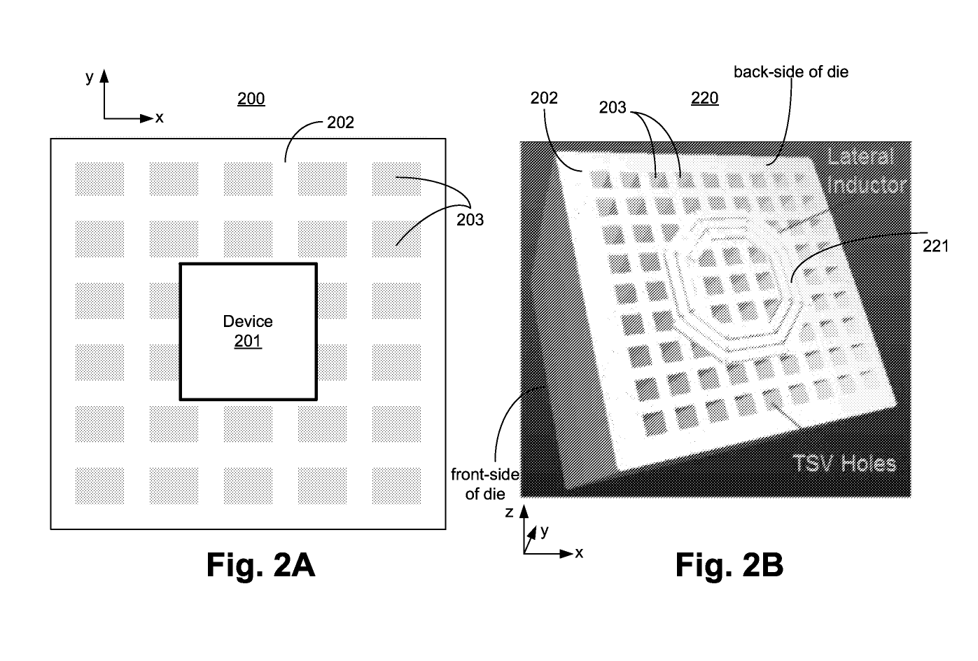

FIG. 2A illustrates a part of a backside of die 200 with a device positioned orthogonal to holes of TSVs, according to some embodiments of the disclosure. It is pointed out that those elements of FIG. 2A having the same reference numbers (or names) as the elements of any other figure can operate or function in any manner similar to that described, but are not limited to such.

In some embodiments, the part of die 200 comprises device 201 and substrate 202 having holes 203 made from TSVs. In some embodiments, TSV holes 203 are round or cylindrical in shape. In some embodiments, TSV holes 203 are square or rectangular shaped. In other embodiments, TSV holes 203 may be of different shapes. In some embodiments, holes 203 are not completely penetrating substrate 202, (i.e., holes 203 are partially penetrating, also referred to as blind TSVs). In some embodiments, the part of die 200 is the backside of the substrate of the die. However, some embodiments are also applicable to front-side of the substrate of the die where most of the active devices are formed.

In some embodiments, device 201 may be any device that exhibits efficiency dependent on substrate conductivity. For example, device 201 may be a MEMs (micro-electro-mechanical systems) device, a transformer, an inductor loop (as shown in FIG. 2B), or any other device that can benefit (e.g., have a higher Q-factor) from a higher impedance patterned substrate. In some embodiments, holes 203 are filled with non-conducting insulating material (e.g., SiO₂). In some embodiments, holes 203 remain unfilled (e.g., filled with air, any gas, or combination of gasses). In some embodiments, some TSV holes 203 are filled with conducting metal (e.g., Cu, Al, etc.) to provide signal routings to device 201.

FIG. 2B illustrates a part of die 220 having a metal loop orthogonal to the holes of TSVs, according to some embodiments of the disclosure. It is pointed out that those elements of FIG. 2B having the same reference numbers (or names) as the elements of any other figure can operate or function in any manner similar to that described, but are not limited to such.

In some embodiments, the part of die 220 comprises a metal loop 221 and a substrate 201 having holes 203 made from TSVs. In some embodiments, the part of die 220 is the backside of the die (i.e., backside of substrate 201). However, some embodiments are also applicable to the front-side of the die (i.e., front-side of substrate 201) where most of the active devices are formed. In some embodiments, metal loop 221 forms an inductor. In some embodiments, metal loop 221 can be of any shape. For example, metal loop may be octagonal, circular, rectangular, etc. In some embodiments, metal loop 221 includes a plurality of concentric loops formed along the same plane or formed as a stack on different planes.

In some embodiments, metal loop 221 comprises two symmetric turns. In one such embodiment, the symmetric turns comprise first and second turns such that the first turn has two terminals one of which is coupled to a terminal of the second turn and the other terminal forms the first electrode of the inductor. In some embodiments, the second turn has two terminals one of which is coupled to a terminal of the first turn and the other terminal of the second turn forms the second electrode of the inductor. In one embodiment, the two electrodes of the inductor are adjacent to each other (i.e., face one another). In one embodiment, first and second electrodes of metal loop 221 are coupled to TSV holes 203 which are filled with conducting metal (e.g., Cu, Al, etc.) to provide signal routings to the first and second terminals.

In some embodiments, metal turn 221 comprises turns (or loops) that stack on top of one another in different metal layers such that each turn in each metal layer is electrically coupled to another turn of a different metal layer to form a stack of spiral inductors. In some embodiments, the stack of spiral inductors is formed orthogonal to patterned substrate 202 with TSV holes 203. In some embodiments, the stack of spiral inductors is of substantially the same diameter and/or width. In some embodiments, the stack of spiral inductors is formed with different diameters and/or width to provide the effects of field shaping. In other embodiments, other types of inductor shapes and number of turns may be used with the patterned substrate with TSV holes 203.

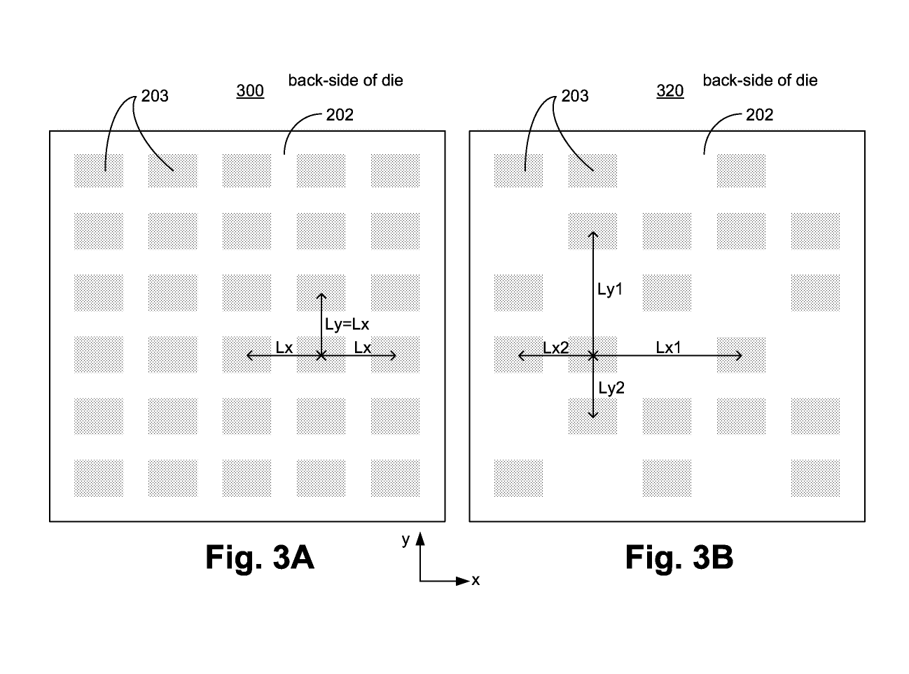

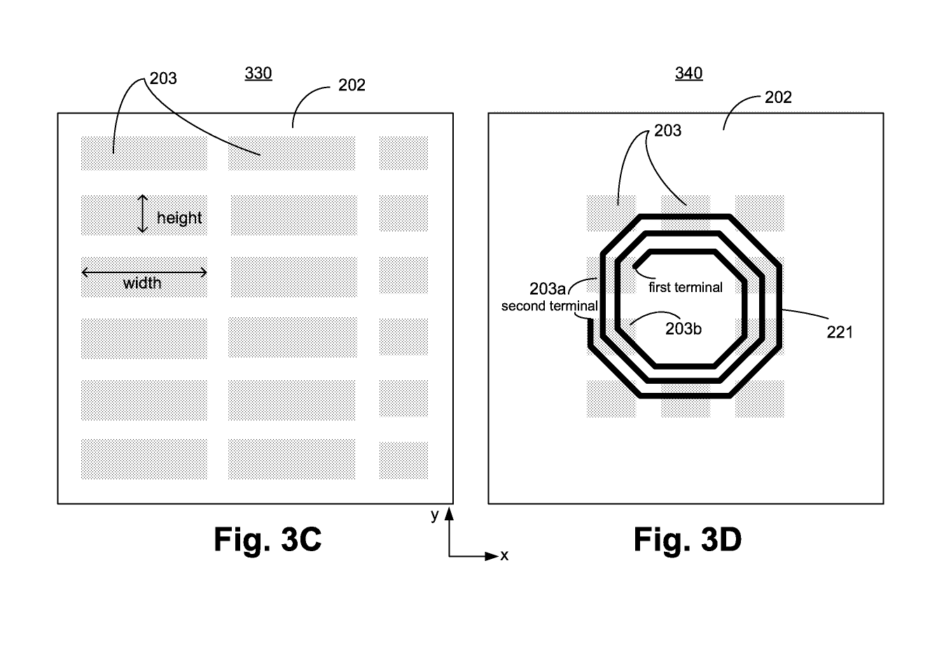

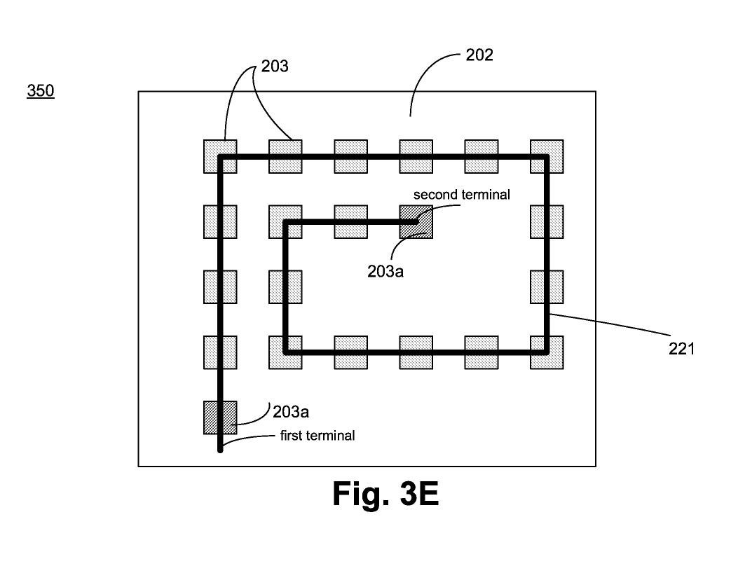

FIG. 3A illustrates a layer 300 of uniform pattern of holes of TSVs orthogonal to a metal loop, according to some embodiments of the disclosure. It is pointed out that those elements of FIG. 3A having the same reference numbers (or names) as the elements of any other figure can operate or function in any manner similar to that described, but are not limited to such.

In some embodiments, each TSV hole 203 is separated from the adjacent TSV hole in substrate 202 by the same horizontal and vertical distances. For example, the distances Lx from the center of a TSV hole to the center of adjacent TSV holes along the same axis (here, x-axis) is the same distance, and is equal to the distance Ly from the center of a TSV hole to the center of adjacent TSVs along the y-axis (i.e., Lx=Ly).

FIG. 3B illustrates a layer 320 of sparsely spaced holes of TSVs orthogonal to a metal turn (or loop), according to some embodiments of the disclosure. It is pointed out that those elements of FIG. 3B having the same reference numbers (or names) as the elements of any other figure can operate or function in any manner similar to that described, but are not limited to such.

In some embodiments, each TSV hole 203 is separated from the adjacent TSV hole in substrate 202 by different horizontal and vertical distances. For example, the distance Lx1 from the center of a TSV hole to the center of an adjacent TSV hole along the x-axis to the right is different from the distance Lx2 from the center of the TSV hole to the center of another adjacent TSV hole along the x-axis. Likewise, the distance Ly1 from the center of a TSV hole to the center of an adjacent TSV hole along the y-axis to the right is different from the distance Ly2 from the center of the TSV hole to the center of another adjacent TSV hole along the y-axis. Other combinations of proportionality of distances may be used to form a sparsely populated plurality of holes made with TSVs. Unlike the embodiments of FIG. 3A, in this embodiment, fewer TSV holes are used (i.e., a pattern of sparsely spaced TSV holes 203 in substrate 202).

FIG. 3C illustrates a layer 330 of uniform pattern of wider holes of TSVs (i.e., wider than those of FIG. 3A) orthogonal to a metal loop, according to some embodiments of the disclosure. It is pointed out that those elements of FIG. 3C having the same reference numbers (or names) as the elements of any other figure can operate or function in any manner similar to that described, but are not limited to such. In some embodiments, TSV holes 203 have different heights and widths when viewed from the top (i.e., the holes can be wider or elongated). Such embodiments may provide more mechanical strength to the die than the patterns of TSVs of FIGS. 3A and 3B.

FIGS. 3D-E illustrate layers 340 and 350 respectively, each having a pattern of holes of TSVs directly orthogonal to a metal turn, according to some embodiments of the disclosure. It is pointed out that those elements of FIGS. 3D-E having the same reference numbers (or names) as the elements of any other figure can operate or function in any manner similar to that described, but are not limited to such.

In some embodiments, each TSV hole is formed underneath the metal turn 221. In some embodiments, fewer TSV holes are made compared to the embodiments of FIGS. 3A-C. In some embodiments, TSV holes 203a and 203b are filled with conductive material (while other TSV holes 203 are unfilled or filled with non-conductive material) to couple to the first and second terminals of metal loop 221.

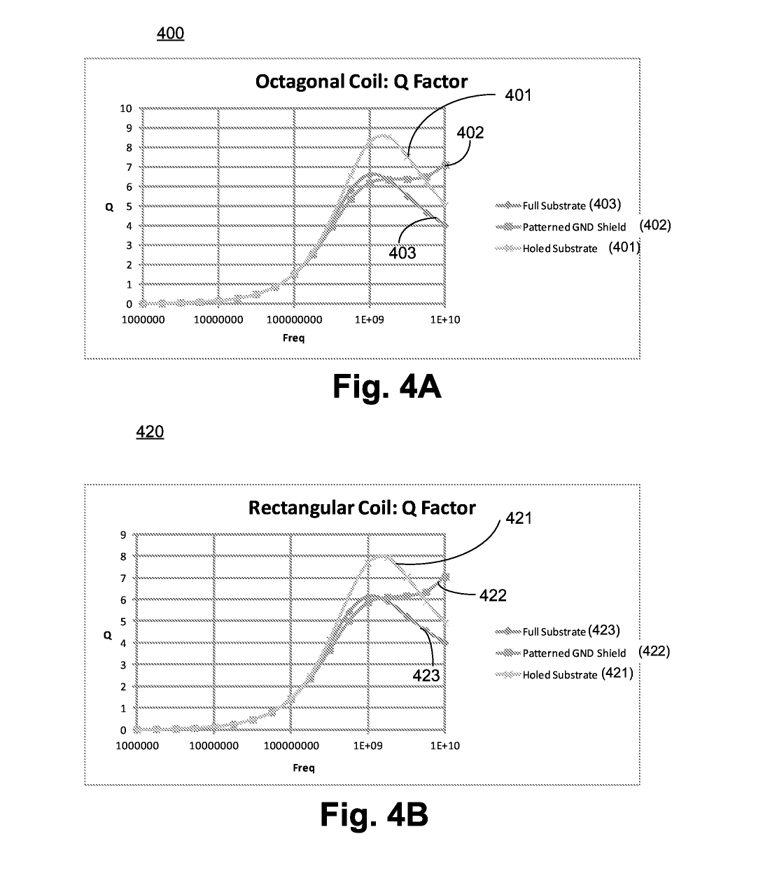

FIGS. 4A-B illustrate plots 400 and 420 indicating improvement in Q-factor using the embodiments compared to prior art approaches. It is pointed out that those elements of FIGS. 4A-B having the same reference numbers (or names) as the elements of any other figure can operate or function in any manner similar to that described, but are not limited to such. Here, x-axis is frequency and y-axis is Q-factor (i.e., inductor efficiency). Each plot shows three waveforms.

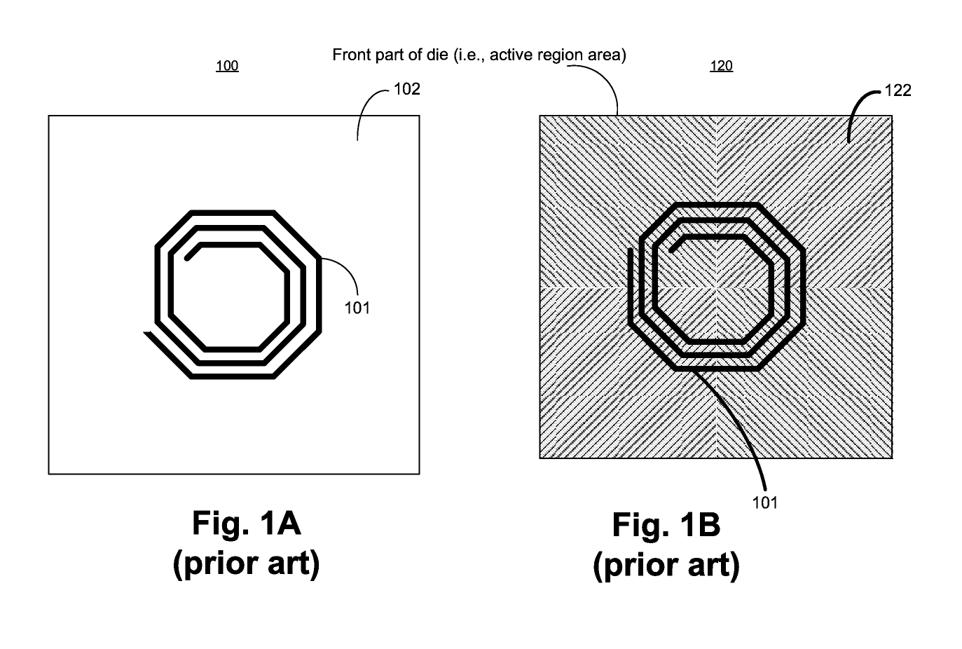

In plot 400, waveform 401 is the case of FIG. 2B where uniform holes are formed underneath an octagonal inductor coil; waveform 402 is the case of FIG. 1B where patterned ground shield is used underneath an octagonal inductor coil; and waveform 403 is the case of FIG. 1A where a solid ground shield is used underneath an octagonal inductor coil. Plot 400 shows that the Q-factor at the frequency of interest for waveform 401 is much higher than Q-factors of waveforms 402 and 403.

In plot 420, waveform 421 is the case where uniform holes are formed underneath a rectangular inductor coil; waveform 422 is the case where patterned ground shield is used underneath a rectangular inductor coil; and waveform 423 is the case where a solid ground shield is used underneath a rectangular inductor coil. Plot 420 shows that the Q-factor for waveform 421 at the frequency of interest is much higher than Q-factors of waveforms 422 and 423. The plots 400 and 420 also show that the octagonal inductor coil shape provides a higher Q-factor than the Q-factor of a rectangular coil shape for the metal loop.

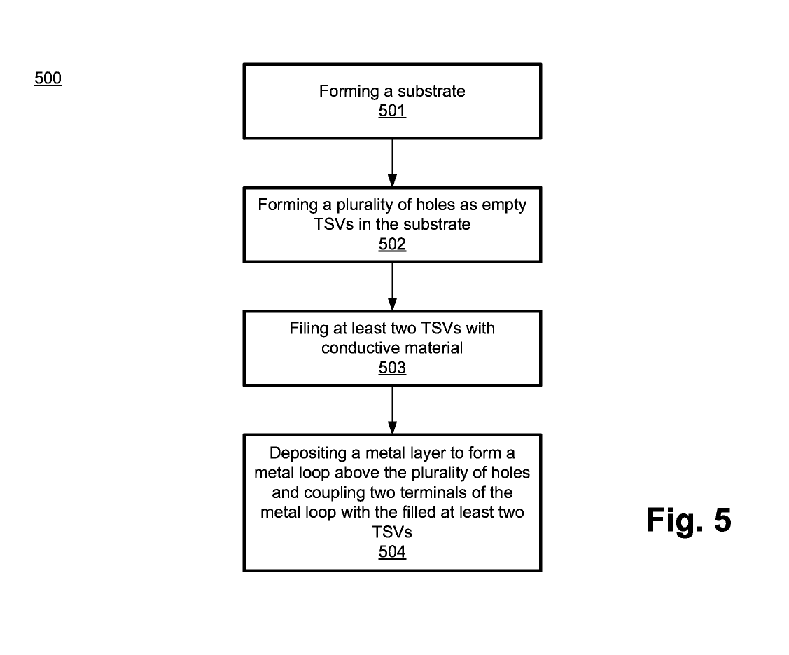

FIG. 5 illustrates a method 500 of forming an inductor with an orthogonal layer of TSV holes, according to some embodiments of the disclosure. It is pointed out that those elements of FIG. 5 having the same reference numbers (or names) as the elements of any other figure can operate or function in any manner similar to that described, but are not limited to such.

Although the blocks in the flowchart with reference to FIG. 5 are shown in a particular order, the order of the actions can be modified. Thus, the illustrated embodiments can be performed in a different order, and some actions/blocks may be performed in parallel. Some of the blocks and/or operations listed in FIG. 5 are optional in accordance with certain embodiments. The numbering of the blocks presented is for the sake of clarity and is not intended to prescribe an order of operations in which the various blocks must occur. Additionally, operations from the various flows may be utilized in a variety of combinations. The embodiment here is described with reference to FIG. 2B.

At block 501, substrate 202 is formed which has a front-side and a backside. The front-side of substrate 202 is the region having active devices. The backside of substrate 202 is the region where the inductor is formed according to some embodiments. At block 502, a plurality of holes 203 is formed on the backside of substrate 202 as unfilled TSVs. As described with reference to FIGS. 3A-D, various types of patterns for the plurality of holes may be used. Referring back to FIG. 5, at block 503, at least two of the TSV holes are filled with conductive material while other TSV holes are either left empty (e.g., air or other gasses) or filled with non-conductive (i.e., insulating) material (e.g., SiO₂). One reason for the two TSV holes to have conductive material is to provide signaling TSVs for connecting the signaling TSVs to device 201.

In some embodiments, device 201 is a metal loop (or turn) 221 that forms an inductor. In other embodiments, other types of devices may be used for device 201. For example, device 201 may be a transformer, a MEMs device, etc. At block 504, a metal layer is deposited to form a metal loop 221 above the plurality of holes 203. In one embodiment, the metal loop 221 has two terminals (or electrodes) each of which is coupled to one of the TSVs filled with conductive material.

In some embodiments, method 500 further comprises uniformly spacing each of the holes from one another. In one embodiment, method 500 comprises forming the plurality of holes as a sparse pattern. In one embodiment, method 500 comprises forming the plurality of holes underneath the metal loop such that a pattern of the plurality of holes follows a shape of the metal loop.

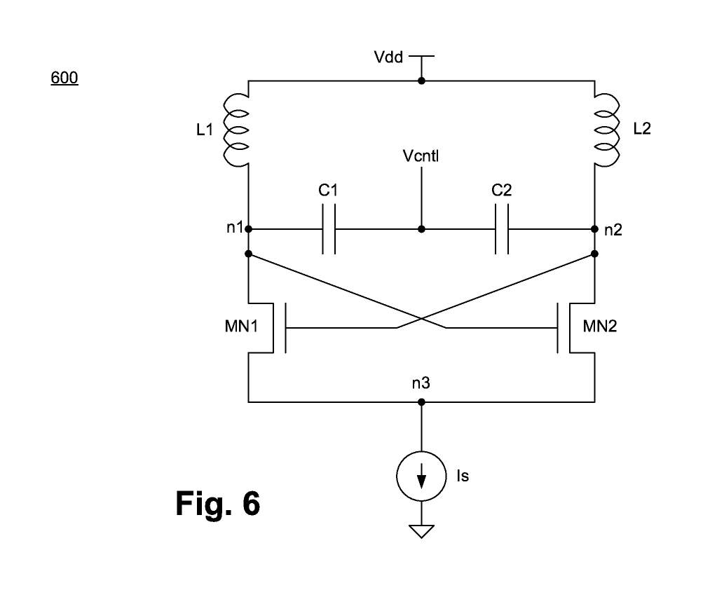

FIG. 6 illustrates an LC oscillator 600 using the inductor with an orthogonal layer of TSV holes, according to some embodiments of the disclosure. It is pointed out that those elements of FIG. 6 having the same reference numbers (or names) as the elements of any other figure can operate or function in any manner similar to that described, but are not limited to such.

In some embodiments, LC oscillator 600 includes an LC tank formed from inductors L1 and L2, and capacitors C1 and C2 coupled together as shown. In some embodiments, LC oscillator 600 further comprises cross-coupled n-type transistors MN1 and MN2, and a current source Is. In some embodiments, first terminals of each inductor are coupled to Vdd (power supply) and the second terminals of each inductor are coupled to nodes n1 and n2, respectively. Capacitors C1 and C2 are coupled in series with a common node controllable by Vcntl (i.e., voltage control signal). By adjusting the voltage level of Vcntl, oscillation frequency of LC oscillator 600 changes. Here, nodes n1 and n2 provide the outputs of LC oscillator 600.

The gate terminal of MN1 is coupled to node n2 and the gate terminal of MN2 is coupled to node n1. The source terminals of MN1 and MN2 are coupled to node n3 which is also coupled to current source Is. The drain terminals of MN1 and MN2 are coupled to nodes n1 and n2 respectively. In some embodiments, inductors L1 and L2 are formed with an orthogonal layer of TSV holes as described with reference to various embodiments.

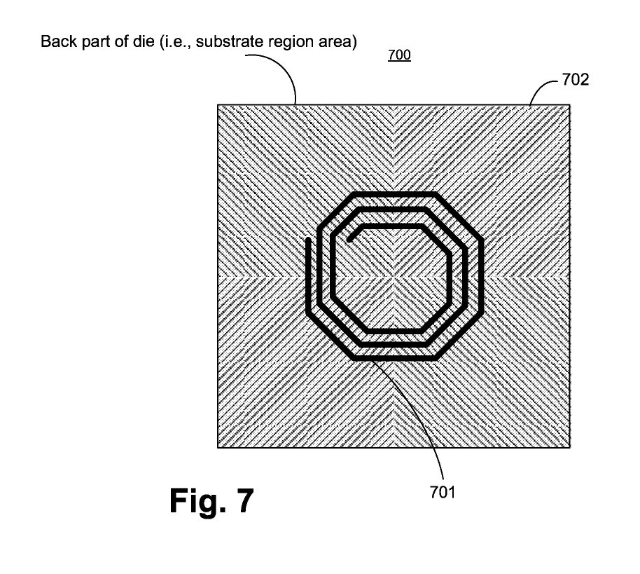

FIG. 7 illustrates a backside of die 700 having an inductor 701 formed orthogonal to a layer of patterned ground shield 702, according to some embodiments of the disclosure. It is pointed out that those elements of FIG. 7 having the same reference numbers (or names) as the elements of any other figure can operate or function in any manner similar to that described, but are not limited to such.

Some embodiments of FIG. 7 are similar to the inductor of FIG. 1B except that here the patterned metal layer 702 is formed on the backside of the die (i.e., backside of the substrate) while the patterned metal layer 102 of FIG. 1B is formed on the front-side (i.e., active region side or front-side of the substrate) of the die. By forming the inductor using the layer of patterned ground shield 702, signal interconnects routing on the active region of die are not disturbed. This frees up space for routing signals in the active side of the die while the inductor is formed on the backside of the die according to various embodiments described.

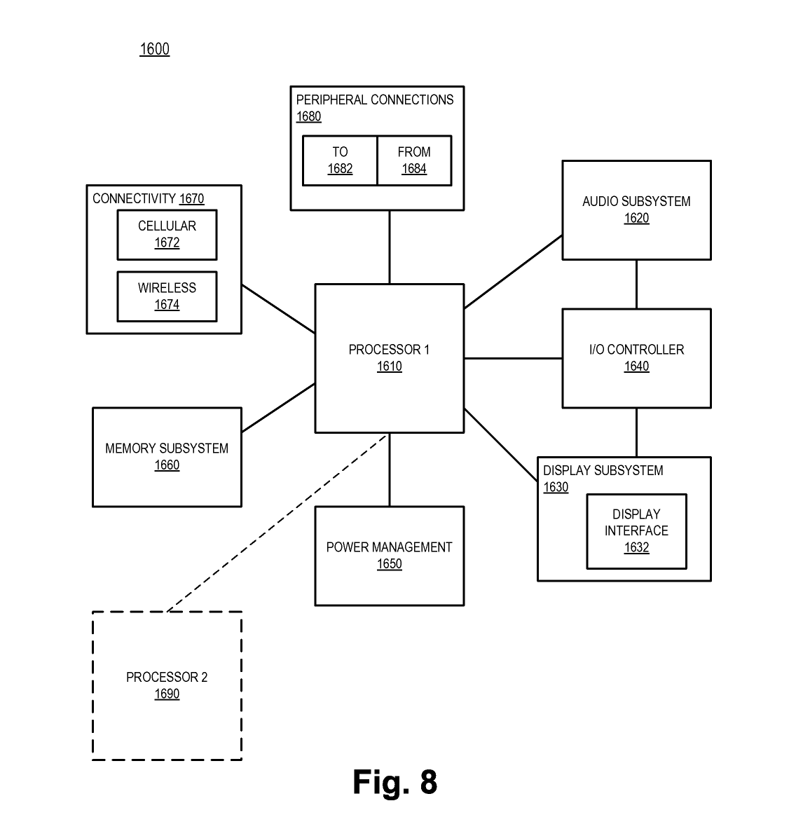

FIG. 8 illustrates a smart device or a computer system or an SoC having a metal loop formed orthogonal to holes of TSVs, according to some embodiments of the disclosure. It is pointed out that those elements of FIG. 8 having the same reference numbers (or names) as the elements of any other figure can operate or function in any manner similar to that described, but are not limited to such.

FIG. 8 illustrates a block diagram of an embodiment of a mobile device in which flat surface interface connectors could be used. In one embodiment, computing device 1600 represents a mobile computing device, such as a computing tablet, a mobile phone or smart-phone, a wireless-enabled e-reader, or other wireless mobile device. It will be understood that certain components are shown generally, and not all components of such a device are shown in computing device 1600.

In one embodiment, computing device 1600 includes a first processor 1610 having a metal loop formed orthogonal to the holes of TSVs, according to the embodiments discussed. Other blocks of the computing device 1600 may also include the apparatus having a metal loop formed orthogonal to the holes of TSVs of the embodiments. In some embodiments, first processor 1610 does not have a metal loop formed orthogonal to the holes of TSVs, but components (or blocks) may have them. The various embodiments of the present disclosure may also comprise a network interface within 1670 such as a wireless interface so that a system embodiment may be incorporated into a wireless device, for example, cell phone or personal digital assistant.

In one embodiment, processor 1610 (and/or processor 1690) can include one or more physical devices, such as microprocessors, application processors, microcontrollers, programmable logic devices, or other processing means. The processing operations performed by processor 1610 include the execution of an operating platform or operating system on which applications and/or device functions are executed. The processing operations include operations related to I/O (input/output) with a human user or with other devices, operations related to power management, and/or operations related to connecting the computing device 1600 to another device. The processing operations may also include operations related to audio I/O and/or display I/O.

In one embodiment, computing device 1600 includes audio subsystem 1620, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 1600, or connected to the computing device 1600. In one embodiment, a user interacts with the computing device 1600 by providing audio commands that are received and processed by processor 1610.

Display subsystem 1630 represents hardware (e.g., display devices) and software (e.g., drivers) components that provide a visual and/or tactile display for a user to interact with the computing device 1600. Display subsystem 1630 includes display interface 1632, which includes the particular screen or hardware device used to provide a display to a user. In one embodiment, display interface 1632 includes logic separate from processor 1610 to perform at least some processing related to the display. In one embodiment, display subsystem 1630 includes a touch screen (or touch pad) device that provides both output and input to a user.

I/O controller 1640 represents hardware devices and software components related to interaction with a user. I/O controller 1640 is operable to manage hardware that is part of audio subsystem 1620 and/or display subsystem 1630. Additionally, I/O controller 1640 illustrates a connection point for additional devices that connect to computing device 1600 through which a user might interact with the system. For example, devices that can be attached to the computing device 1600 might include microphone devices, speaker or stereo systems, video systems or other display devices, keyboard or keypad devices, or other I/O devices for use with specific applications such as card readers or other devices.

As mentioned above, I/O controller 1640 can interact with audio subsystem 1620 and/or display subsystem 1630. For example, input through a microphone or other audio device can provide input or commands for one or more applications or functions of the computing device 1600. Additionally, audio output can be provided instead of, or in addition to display output. In another example, if display subsystem 1630 includes a touch screen, the display device also acts as an input device, which can be at least partially managed by I/O controller 1640. There can also be additional buttons or switches on the computing device 1600 to provide I/O functions managed by I/O controller 1640.

In one embodiment, I/O controller 1640 manages devices such as accelerometers, cameras, light sensors or other environmental sensors, or other hardware that can be included in the computing device 1600. The input can be part of direct user interaction, as well as providing environmental input to the system to influence its operations (such as filtering for noise, adjusting displays for brightness detection, applying a flash for a camera, or other features).

In one embodiment, computing device 1600 includes power management 1650 that manages battery power usage, charging of the battery, and features related to power saving operation. Memory subsystem 1660 includes memory devices for storing information in computing device 1600. Memory can include nonvolatile (state does not change if power to the memory device is interrupted) and/or volatile (state is indeterminate if power to the memory device is interrupted) memory devices. Memory subsystem 1660 can store application data, user data, music, photos, documents, or other data, as well as system data (whether long-term or temporary) related to the execution of the applications and functions of the computing device 1600.

Elements of embodiments are also provided as a machine-readable medium (e.g., memory 1660) for storing the computer-executable instructions (e.g., instructions to implement any other processes discussed herein). The machine-readable medium (e.g., memory 1660) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 1670 includes hardware devices (e.g., wireless and/or wired connectors and communication hardware) and software components (e.g., drivers, protocol stacks) to enable the computing device 1600 to communicate with external devices. The computing device 1600 could be separate devices, such as other computing devices, wireless access points or base stations, as well as peripherals such as headsets, printers, or other devices.

Connectivity 1670 can include multiple different types of connectivity. To generalize, the computing device 1600 is illustrated with cellular connectivity 1672 and wireless connectivity 1674. Cellular connectivity 1672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 1674 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 1680 include hardware interfaces and connectors, as well as software components (e.g., drivers, protocol stacks) to make peripheral connections. It will be understood that the computing device 1600 could both be a peripheral device (“to” 1682) to other computing devices, as well as have peripheral devices (“from” 1684) connected to it. The computing device 1600 commonly has a “docking” connector to connect to other computing devices for purposes such as managing (e.g., downloading and/or uploading, changing, synchronizing) content on computing device 1600. Additionally, a docking connector can allow computing device 1600 to connect to certain peripherals that allow the computing device 1600 to control content output, for example, to audiovisual or other systems.

In addition to a proprietary docking connector or other proprietary connection hardware, the computing device 1600 can make peripheral connections 1680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. For example, other memory architectures e.g., Dynamic RAM (DRAM) may use the embodiments discussed. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

For example, an apparatus is provided which comprises: a substrate; a plurality of holes formed as vias in the substrate; and a metal loop formed in a metal layer positioned above the plurality of holes such that a plane of the metal loop is orthogonal to the plurality of holes. In some embodiments, most of the plurality of holes is filled with an insulating material. In some embodiments, at least two vias of at least two holes of the plurality of holes are filled with conductive material to physically couple to two terminals of the metal loop to form an inductor. In some embodiments, the holes of the plurality are uniformly spaced form one another.

In some embodiments, the holes of the plurality are formed as a sparse pattern of holes. In some embodiments, the plurality of holes is formed underneath the metal loop such that a pattern of the plurality of holes follows a shape of the metal loop. In some embodiments, the plurality of holes is formed in the backside of the substrate of a die. In some embodiments, the plurality of holes is formed in the front-side of the substrate, the front-side having an active region of the die. In some embodiments, the metal loop comprises multiple metal loops. In some embodiments, the plurality of holes is partially penetrating the substrate.

In another example, a system comprises: a memory; a processor coupled to the memory, the processor comprising an apparatus according to the apparatus described above; and a wireless interface for allowing the processor to communicate with another device. In some embodiments, the system further comprises a display interface.

In another example, a method is provided which comprises: forming a substrate; forming a plurality of holes as high impedance vias in the substrate; and depositing a metal layer to form a metal loop above the plurality of holes such that a plane of the metal loop is orthogonal to the plurality of holes. In some embodiments, the method comprises filling most of the plurality of holes with an insulating material. In some embodiments, the method comprises: filing at least two vias of at least two holes of the plurality of holes with conductive material; and coupling two terminals of the metal loop with the filled at least two vias.

In some embodiments, the method comprises uniformly spacing each of the holes form one another. In some embodiments, comprises forming the plurality of holes as a sparse pattern. In some embodiments, the method comprises forming the plurality of holes underneath the metal loop such that a pattern of the plurality of holes follows a shape of the metal loop. In some embodiments, the method comprises forming the plurality of holes in backside of the substrate of a die. In some embodiments, the method comprises forming the plurality of holes in front-side of the substrate, the front-side having an active region of the die.

In another example, an apparatus is provided which comprises: means for forming a substrate; means for forming a plurality of holes as high impedance vias in the substrate; and means for depositing a metal layer to form a metal loop above the plurality of holes such that a plane of the metal loop is orthogonal to the plurality of holes. In some embodiments, the apparatus comprises: means for filling most of the plurality of holes with an insulating material.

In some embodiments, the apparatus comprises: means for filing at least two vias of at least two holes of the plurality of holes with conductive material; and means for coupling two terminals of the metal loop with the filled at least two vias. In some embodiments, the apparatus comprises means for uniformly spacing each of the holes form one another. In some embodiments, the apparatus comprises means for forming the plurality of holes as a sparse pattern. In some embodiments, the apparatus comprises means for forming the plurality of holes underneath the metal loop such that a pattern of the plurality of holes follows a shape of the metal loop. In some embodiments, the apparatus comprises means for forming the plurality of holes in backside of the substrate of a die. In some embodiments, the apparatus comprises means for forming the plurality of holes in front-side of the substrate, the front-side having an active region of the die.

In another example, a system comprises: a memory; a processor coupled to the memory, the processor comprising an apparatus according to the apparatus described above; and a wireless interface for allowing the processor to communicate with another device. In some embodiments, the system further comprises a display interface.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1-21. (canceled)

22. An apparatus comprising:
a substrate;
a plurality of holes formed as vias in the substrate; and
a metal loop formed in a metal layer positioned above the plurality of holes such that a plane of the metal loop is orthogonal to the plurality of holes.

23. The apparatus of claim 22, wherein most of the plurality of holes are filled with an insulating material.

24. The apparatus of claim 22, wherein at least two vias of at least two holes of the plurality of holes are filled with conductive material to physically couple to two terminals of the metal loop to form an inductor.

25. The apparatus of claim 22, wherein the plurality of holes are uniformly spaced form one another.

26. The apparatus of claim 22, wherein the plurality of holes are formed as a sparse pattern of holes.

27. The apparatus of claim 22, wherein the plurality of holes are formed underneath the metal loop such that a pattern of the plurality of holes follows a shape of the metal loop.

28. The apparatus of claim 22, wherein the plurality of holes are formed in the backside of the substrate of a die.

29. The apparatus of claim 22, wherein the plurality of holes are formed in the front-side of the substrate, the front-side having an active region of the die.

30. The apparatus of claim 22, wherein the metal loop comprises multiple metal loops.

31. The apparatus of claim 22, wherein the plurality of holes are partially penetrating the substrate.

32. A method comprising:
forming a substrate;
forming a plurality of holes as high impedance vias in the substrate; and
depositing a metal layer to form a metal loop above the plurality of holes such that a plane of the metal loop is orthogonal to the plurality of holes.

33. The method of claim 32 comprises filling most of the plurality of holes with an insulating material.

34. The method of claim 32 comprises:
filing at least two vias of at least two holes of the plurality of holes with conductive material; and
coupling two terminals of the metal loop with the filled at least two vias.

35. The method of claim 32 comprises uniformly spacing each of the holes form one another.

36. The method of claim 32 comprises forming the plurality of holes as a sparse pattern.

37. The method of claim 32 comprises forming the plurality of holes underneath the metal loop such that a pattern of the plurality of holes follows a shape of the metal loop.

38. The method of claim 32 comprises forming the plurality of holes in backside of the substrate of a die.

39. The method of claim 32 comprises forming the plurality of holes in front-side of the substrate, the front-side having an active region of the die.

40. A system comprising:
a memory;
a processor coupled to the memory, the processor comprising:
a substrate;
a plurality of holes formed as vias in the substrate; and
a metal loop formed in a metal layer positioned above the plurality of holes such that a plane of the metal loop is orthogonal to the plurality of holes; and
a wireless interface for allowing the processor to communicate with another device.

41. The system of claim 40 further comprises a display unit.
